(19) United States
(12) Patent Application Publication
(10) Pub. No.: US 2009/0155950 A1
(43) Pub. Date: Jun. 18, 2009

(54) CMOS IMAGE SENSOR AND METHOD FOR FABRICATING THE SAME

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/330,597

(22) Filed: Dec. 9, 2008

(30) Foreign Application Priority Data
Dec. 17, 2007 (KR) 10-2007-0132135

(51) Int. Cl. H01L 31/18

(52) U.S. Cl. 438/70; 257/E31.127

(57) ABSTRACT

A method for fabricating a CMOS image sensor includes sequentially forming an insulating film, a metal pad and a first passivation film over a semiconductor substrate including photodiodes, forming a planarization layer over the first passivation film, forming color filter layers over the planarization layer, forming an overcoating layer over the semiconductor substrate including the color filter layers, forming micro lenses over the overcoating layer, forming a photoresist film over the semiconductor substrate including the first passivation film and the micro lenses, and then etching the first passivation film using the photoresist film as a mask to expose the metal pad.

The present is application claims priority under 35 U.S.C. §119 to Korean Patent Application No. 10-2007-0132135 (filed on Dec. 17, 2007), which is hereby incorporated by reference in its entirety.

### BACKGROUND

An image sensor is a semiconductor device which converts an optical image into an electrical signal. The image sensors are largely classified into a charge coupled device (CCD) and a complementary metal oxide silicon (CMOS) image sensor. The charge coupled device (hereinafter, referred to as a ‘CCD’) includes a plurality of photodiodes (PDs), which are arranged in a matrix, to convert an optical signal into an electrical signal. The CCD includes a plurality of vertical charge coupled devices (VCCDs), which are formed between the photodiodes arranged in a matrix to vertically transmit charges produced in the respective photodiodes, a plurality of horizontal charge coupled devices (HCCDs), which horizontally transmit the charges transmitted by the respective VCCDs, and a sense amplifier which senses the horizontally transmitted charges to output an electrical signal. However, such a CCD has disadvantages of a complicated driving method, high power consumption, and a complicated fabricating process requiring a multi-step photo process. Further, the CCD is required to integrate a control circuit, a signal processing circuit, an analogue/digital conversion circuit (A/D converter), etc. in a CCD chip. Accordingly, it is difficult to reduce the size of the products.

Recently, a CMOS image sensor has been noted as a next-generation image sensor capable of overcoming the disadvantages of the CCD. The CMOS image sensor is a device employing a CMOS technology, which uses a control circuit, a signal processing circuit, etc. as peripheral circuits, such that MOS transistors, having the same number as unit pixels, are formed on a semiconductor substrate, whereby outputs of the respective unit pixels are sequentially detected by the MOS transistors by a switching method. The CMOS image sensor is characterized in that a photodiode and a MOS transistor are formed in a unit pixel to sequentially detect electric signals of the respective unit pixels by a switching method, thereby achieving an image. As a result of employing a CMOS fabrication technology, the CMOS image sensor has several advantages, for example, low power consumption, and a simplified fabricating process based on a reduced number of photo process steps.

FIGS. 1A to 1D illustrate cross-sectional views showing a method for fabricating a CMOS image sensor. First, as shown in FIG. 1A, an insulating film 101 such as a gate insulating film or an interlayer insulating film is formed on and/or over a semiconductor substrate 100. A metal pad 102 for each signal line is formed on and/or over the insulating film 101. A first passivation film 103 such as an oxide film or a nitride film is formed on and/or over the entire surface of the insulating film 101 including the metal pad 102.

Then, as shown in FIG. 1B, a photoresist film 104 is coated on and/or over the first passivation film 103 and is patterned to expose an upper portion of the metal pad 102 by an exposure and development process. The first passivation film 103 is selectively etched using the patterned photoresist film 104 as a mask to form an opening 105 at the metal pad 102.

Then, as shown in FIG. 1C, the photoresist film 104 is removed, and thermal resin (TR) or thin TEOS is deposited on and/or over the entire surface of the semiconductor substrate 100 to protect micro lenses 109 to be fabricated in a subsequent process.

Then, as shown in FIG. 1D, a silicon nitride film or a silicon oxynitride film is deposited on and/or over the entire surface of a second passivation film 110 to form a planarization layer 106. The planarization layer 106 is selectively etched by a photolithography process to remove the planarization layer 106 of a metal pad portion. Then, color filter layers 107 are formed on and/or over the planarization layer 106 corresponding to respective photodiode. In this case, the respective color filter layers are formed by applying respective color resists and performing a photolithography using an additional mask. Then, an overcoating layer 108 is formed on and/or over the entire surface of the substrate including the respective color filter layers 107. The overcoating layer 108 is selectively etched by a photolithography process to remove the overcoating layer 108 of a metal pad portion. Subsequently, a polymeric material is adhered to the overcoating layer 108 to form a material layer for micro lenses. Then, the photoresist film is patterned by an exposure and development process to define a micro lens region. The polymeric material serving as a material layer for micro lenses is selectively patterned using a photoresist film to form a micro lens pattern corresponding to the color filter layers 107. A thermal treatment is performed on the micro lens pattern by a reflow process to form hemispherical micro lenses 109 having a specific curvature.

However, in such a method for fabricating a CMOS image sensor, the second passivation film deposited on and/or over the metal pad region is stripped by subsequent etching processes to cause damage to the metal pad or produce polymer residues. Accordingly, there is a problem of reducing reliability in a process for forming the micro lenses.

### SUMMARY

Embodiments relate to a CMOS image sensor and a method for fabricating the same that removes undesirable polymer residues.

Embodiments relate to a method for fabricating a CMOS image sensor that may include at least one of the following: forming an insulating film, a metal pad and a first passivation film sequentially on and/or over an entire surface of a semiconductor substrate including photodiodes; forming a planarization layer and color filter layers on and/or over the first passivation film; forming at least one metal line on and/or over the transistor; forming a passivation film after an uppermost metal layer is formed on and/or over the metal line; performing annealing at a high temperature after the passivation film is formed; forming an uppermost passivation film on and/or over the passivation film; In accordance with embodiments, a process for forming micro lenses is performed before a process for forming a contact hole. Accordingly, there is an effect of removing polymer residues which may be produced in the pad while protecting the micro lenses.

Embodiments relate to a method that may include at least one of the following: providing a semiconductor substrate having photodiodes; and then sequentially forming an insulating film, a metal pad and a first passivation film over the semiconductor substrate including the photodiodes; and then forming a planarization layer over the first passivation film; and then forming color filter layers over the planarization layer; and then forming an overcoating layer over the semiconductor substrate including the color filter layers; and then forming micro lenses over the overcoating layer; and then forming a photoresist film over the semiconductor substrate including the first passivation film and the micro lenses; and then etching the first passivation film using the photoresist film as a mask to form expose the metal pad.

Embodiments relate to a method that may include at least one of the following: providing a semiconductor substrate having photodiodes; and then forming a first insulating film over the semiconductor substrate including the photodiodes; and then forming a metal pad over the first insulating film; and then forming a second insulating film over the first insulating film including the metal pad; and then forming a third insulating film over the second insulating film; and then forming a nitride layer over the third insulating film; and then forming color filter layers over the nitride layer; and then forming an overcoating layer over the color filter layers; and then forming micro lenses over the overcoating layer; and then forming a photoresist film over the semiconductor substrate including the third insulating film and the micro lenses; and then etching the third insulating film using the photoresist film as a mask to expose the metal pad and then removing the photoresist film.

Embodiments relate to a method that may include at least one of the following: providing a semiconductor substrate having photodiodes; and then forming a first insulating film over the semiconductor substrate including the photodiodes; and then forming a metal pad over the first insulating film; and then forming a second insulating film over the first insulating film including the metal pad; and then forming a nitride layer over the second insulating film; and then forming color filter layers over the nitride layer; and then forming an overcoating layer over the color filter layers; and then forming micro lenses over the overcoating layer; and then forming a photoresist film over the semiconductor substrate including the second insulating film and the micro lenses; and then etching the second insulating film using the photoresist film as a mask to expose the metal pad and then removing the photoresist film.

### DRAWINGS

FIGS. 1A to 1D illustrate a method for fabricating a CMOS image sensor.

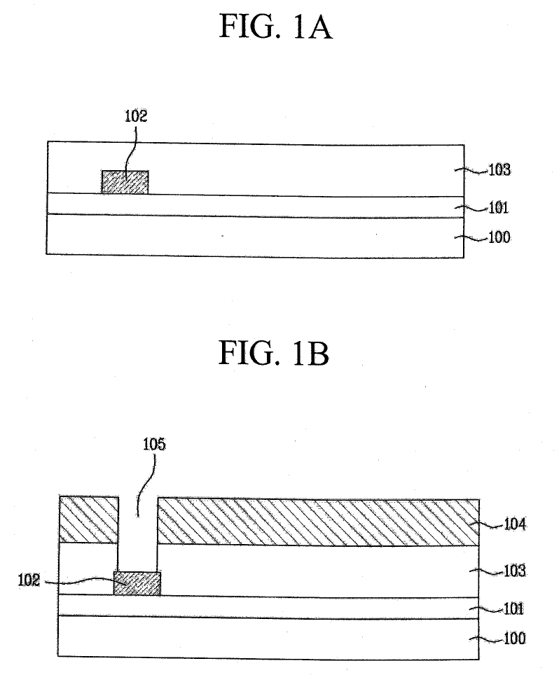

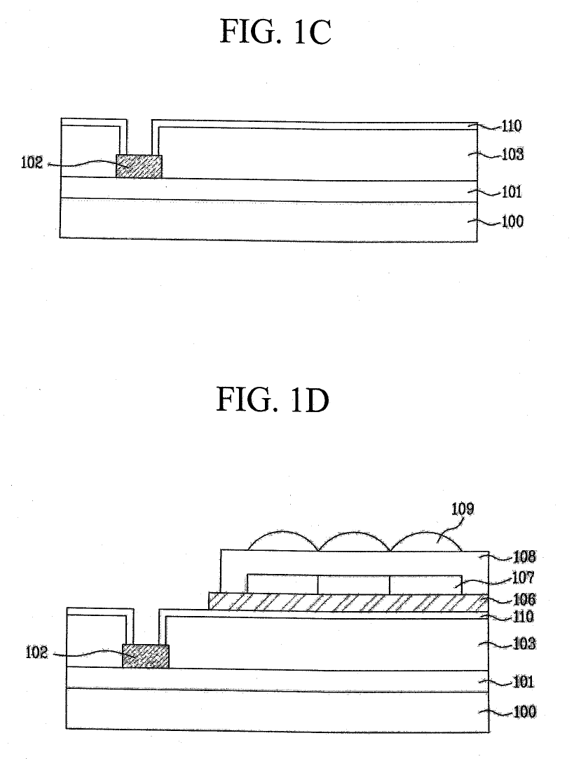

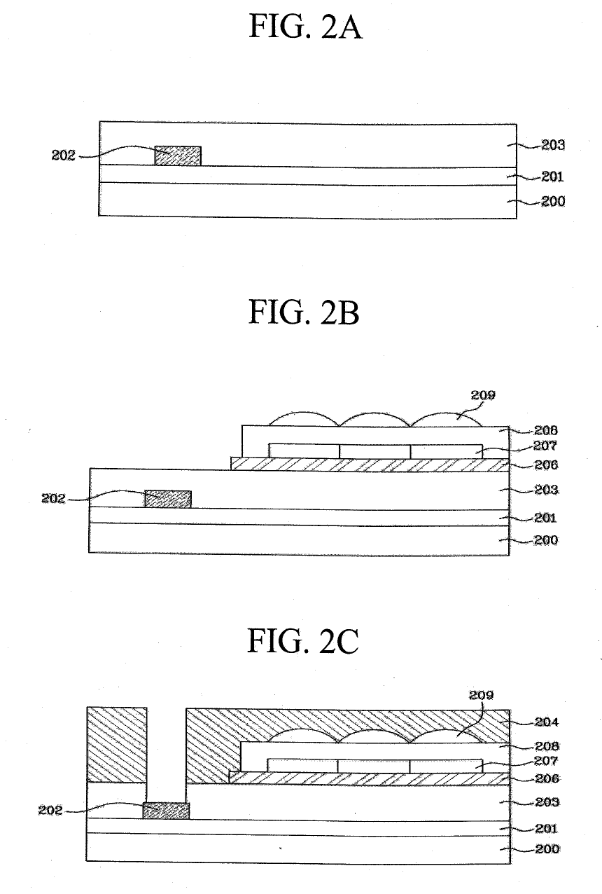

Example FIGS. 2A to 2C illustrate a method for fabricating a CMOS image sensor in accordance with embodiments.

### DESCRIPTION

As shown in example FIG. 2A, an insulating film 201 such as a gate insulating film or an interlayer insulating film is formed on and/or over a semiconductor substrate 200. A metal pad 202 for each signal line is formed on and/or over the insulating film 201. A first passivation film 203 such as an oxide film or a nitride film is formed on and/or over the entire surface of the insulating film 201 including the metal pad 202. Before the first passivation film 203 is formed, a second passivation film may be formed on and/or over the entire surface of the insulating film 201 using thermal resin (TR) or thin tetra-ethyl-ortho-silicate (TEOS) having a thickness in a range between approximately 10 to 5000 Å to protect the metal pad 202 by preventing loss of the metal pad 202 due to an etching process.

Then, as shown in example FIG. 2B, a silicon nitride film or a silicon oxynitride film is deposited on and/or over the entire surface of the semiconductor substrate 200 to form a planarization layer 206. The planarization layer 206 is selectively etched by a photolithography process to remove a portion of the planarization layer 206 formed on and/or over a metal pad region. Color filter layers 207 are formed on and/or over the planarization layer 206 corresponding to respective photodiode regions. The color filter layers are formed by applying respective color resists and performing a photolithography using an additional mask. An overcoating layer 208 is formed on and/or over the entire surface of the substrate including the color filter layers 207. The overcoating layer 208 is selectively etched by a photolithography process to remove a portion of the overcoating layer 208 formed on and/or over the metal pad region.

Subsequently, a polymeric material is adhered or otherwise formed on and/or over the overcoating layer 208 to form a material layer for micro lenses. Then, the photoresist film is etched by an exposure and development process to define a micro lens region. Then, the polymeric material serving as a material layer for micro lenses is selectively patterned using a photoresist film to form a micro lens pattern spatially corresponding to the color filter layers 207. A thermal treatment is performed on and/or over the micro lens pattern by a reflow process to form micro lenses 209 having a hemispherical cross-section with a specific curvature.

Then, as shown in example FIG. 2C, a photoresist film 204 is coated on and/or over the semiconductor substrate 200 including the micro lenses 209 and is etched to expose an upper portion of the metal pad 202 by an exposure and development process. The first passivation film 203 is selectively etched using the etched photoresist film 204 as a mask to form an opening at the metal pad 202. Then, the photoresist film 204 is removed by a thinner process.

Accordingly, the photoresist film can protect the micro lenses when the polymer residues, produced when exposing the metal pad are removed. Thus, the polymer residues can be completely removed without damage to the micro lenses. Further, it is possible to prevent damage of the metal pad due to etching processes performed when the micro lenses are formed.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate having photodiodes; and then
sequentially forming an insulating film, a metal pad and a first passivation film over the semiconductor substrate including the photodiodes; and then
forming a planarization layer over the first passivation film; and then
forming color filter layers over the planarization layer; and then
forming an overcoating layer over the semiconductor substrate including the color filter layers; and then
forming micro lenses over the overcoating layer; and then forming a photoresist film over the semiconductor substrate including the first passivation film and the micro lenses; and then etching the first passivation film using the photoresist film as a mask to expose the metal pad.

2. The method of claim 1, further comprising removing the photoresist film after etching the first passivation layer.

3. The method of claim 2, wherein the photoresist film is removed by a thinner process.

4. The method of claim 1, further comprising forming a second passivation film between the insulating film and the first passivation film.

5. The method of claim 4, wherein the second passivation film is formed of thermal resin (TR).

6. The method of claim 1, further comprising forming a second passivation film between the insulating film and the first passivation film, wherein the second passivation film comprises tetra-ethyl-ortho-silicate.

7. The method of claim 6, wherein the tetra-ethyl-ortho-silicate has a thickness in a range between approximately 10 to 5000 Å.

8. A method comprising:
providing a semiconductor substrate having photodiodes; and then
forming a first insulating film over the semiconductor substrate including the photodiodes; and then
forming a metal pad over the first insulating film; and then
forming a second insulating film over the first insulating film including the metal pad; and then
forming a third insulating film over the second insulating film; and then
forming a nitride layer over the third insulating film; and then
forming color filter layers over the nitride layer; and then
forming an overcoating layer over the color filter layers; and then
forming micro lenses over the overcoating layer; and then
forming a photoresist film over the semiconductor substrate including the third insulating film and the micro lenses; and then
etching the third insulating film using the photoresist film as a mask to expose the metal pad and then removing the photoresist film.

9. The method of claim 8, wherein the second insulating film comprises thermal resin (TR).

10. The method of claim 9, wherein the TR has a thickness in a range between approximately 10 to 5000 Å.

11. The method of claim 8, wherein the second insulating film comprises tetra-ethyl-ortho-silicate (TEOS).

12. The method of claim 11, wherein the TEOS has a thickness in a range between approximately 10 to 5000 Å.

13. The method of claim 8, wherein the third insulating film comprises an oxide film.

14. The method of claim 8, wherein the third insulating film comprises a nitride film.

15. The method of claim 8, wherein the nitride layer comprises silicon nitride.

16. The method of claim 8, wherein the nitride layer comprises silicon oxynitride.

17. The method of claim 8, wherein forming the nitride layer comprises:
forming the nitride layer over the third insulating film; and then
performing an etching process on the nitride layer to remove a portion of the nitride layer formed over a metal pad region.

18. The method of claim 8, wherein forming the overcoating layer comprises:
forming the overcoating layer over the color filter layers; and then
performing an etching process on the overcoating layer to remove a portion of the overcoating layer formed over a metal pad region.

19. The method of claim 8, wherein the photoresist film is removed by a thinner process.

20. A method comprising:
providing a semiconductor substrate having photodiodes; and then
forming a first insulating film over the semiconductor substrate including the photodiodes; and then
forming a metal pad over the first insulating film; and then
forming a second insulating film over the first insulating film including the metal pad; and then
forming a nitride layer over the second insulating film; and then
forming color filter layers over the nitride layer; and then
forming an overcoating layer over the color filter layers; and then
forming micro lenses over the overcoating layer; and then
forming a photoresist film over the semiconductor substrate including the second insulating film and the micro lenses; and then
etching the second insulating film using the photoresist film as a mask to expose the metal pad and then removing the photoresist film.
